(19) United States
(12) Patent Application Publication
(10) Pub. No.: US 2019/0229047 A1
(43) Pub. Date: Jul. 25, 2019

(54) FAN-OUT SEMICONDUCTOR PACKAGE

(71) Applicant: SAMSUNG ELECTRO-MECHANICS CO., LTD., Suwon-Si (KR)

(72) Inventors: So Yeon MOON, Suwon-Si (KR); Gun LEE, Suwon-Si (KR); Jun Hyeong PARK, Suwon-Si (KR)

(21) Appl. No.: 16/132,957

(22) Filed: Sep. 17, 2018

(30) Foreign Application Priority Data
Jan. 19, 2018 (KR) 10-2018-0007332

(51) Int. Cl. H01L 23/498; H01L 23/31; H01L 23/522; H01L 23/48; H01L 27/146; H01L 23/00; H01L 23/64; H05K 1/02

(52) U.S. Cl. CPC H01L 23/49822; H01L 23/3114; H01L 23/49816; H01L 23/49827; H01L 23/522; H01L 23/481; H01L 2924/14; H01L 24/02; H01L 23/642; H05K 1/0231; H01L 2224/02379; H01L 2224/04105; H01L 2924/15311; H01L 27/14618

(57) ABSTRACT

A fan-out semiconductor package includes: a semiconductor chip; a passive element disposed side by side with the semiconductor chip in a horizontal direction; a redistribution member electrically connected to the semiconductor chip and the passive element and disposed beneath the semiconductor chip and the passive element; and an encapsulant encapsulating the semiconductor chip and the passive element, wherein the redistribution member includes passive element connection vias having a rectangular transverse cross section for the purpose of electrical connection to the passive element.

### CROSS-REFERENCE TO RELATED APPLICATION(S)

This application claims the benefit of priority to Korean Patent Application No. 10-2018-0007332 filed on Jan. 19, 2018, in the Korean Intellectual Property Office, the disclosure of which is incorporated herein by reference in its entirety.

### TECHNICAL FIELD

The present disclosure relates to a fan-out semiconductor package.

### BACKGROUND

A fan-out semiconductor package refers to package technology for electrically connecting a semiconductor chip to a printed circuit board (PCB), such as a mainboard of an electronic device, or the like, and protecting the semiconductor chip from external impacts. Meanwhile, a prominent recent trend in the development of technology related to semiconductor chips is to reduce a size of semiconductor chips. Therefore, in a package field, in accordance with a rapid increase in demand for compact semiconductor chips, or the like, implementation of a fan-out semiconductor package having a compact size and including a plurality of pins has been demanded.

One type of package technology suggested in order to satisfy the technical demand as described above is a wafer level package (WLP) using redistribution of connection pads of a semiconductor chip formed on a wafer. Examples of wafer level packages include a fan-in WLP and a fan-out WLP.

In a fan-out semiconductor package, recently, in accordance with performance improvement and miniaturization of electronic devices, attempts to dispose as many semiconductor chips, passive elements, or the like, as possible in a limited space of the fan-out semiconductor package are being continuously made.

### SUMMARY

An aspect of the present disclosure may provide a fan-out semiconductor package in which electrical connection to a passive element may be easily performed even in the case that a manufacturing error occurs.

An aspect of the present disclosure may also provide a fan-out semiconductor package in which contact areas between a passive element and vias may be increased.

According to an aspect of the present disclosure, a fan-out semiconductor package may include: a semiconductor chip; a passive element disposed side by side with the semiconductor chip in a horizontal direction; a redistribution member electrically connected to the semiconductor chip and the passive element and disposed beneath the semiconductor chip and the passive element; and an encapsulant encapsulating the semiconductor chip and the passive element, wherein the redistribution member includes passive element connection vias having a rectangular transverse cross section for the purpose of electrical connection to the passive element.

The passive element connection via may have the same width as that of an external electrode provided on the passive element.

A lower end portion of the passive element connection via may have the same width as that of an external electrode provided on the passive element, and an upper end portion of the passive element connection via may have a width greater than that of the external electrode provided on the passive element.

A plurality of passive element connection vias may be disposed side by side in a length direction on each of external electrodes disposed on opposite end portions of the passive element.

The plurality of passive element connection vias may be disposed to be spaced apart from each other in a length direction.

The redistribution member may include chip connection vias connected to the semiconductor chip, and the chip connection vias may be disposed to be spaced apart from the passive element connection vias.

A longitudinal cross section of the chip connection via may have any one of a tapered shape and a cylindrical shape.

The fan-out semiconductor package may further include a core member including a through-hole in which the semiconductor chip and the passive element are disposed.

The core member may include an insulating layer in which the through-hole is formed, a pattern layer formed on at least one of an upper surface and a lower surface of the insulating layer, and connection vias connected to the pattern layer.

The fan-out semiconductor package may further include a core member including a first through-hole in which the semiconductor chip is disposed and a second through-hole, disposed to be spaced apart from the first through-hole and in which the passive element is disposed.

The redistribution member may include chip connection vias connected to the semiconductor chip and the passive element connection vias connected to the passive element.

The core member may only include an insulating layer.

A longitudinal cross section of the chip connection via may have any one of a tapered shape and a cylindrical shape, and the passive element connection via may have the same width as that of an external electrode provided on the passive element.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is ultimately mounted on a mainboard of an electronic device;

FIG. 6 is a schematic cross-sectional view illustrating a case in which a fan-in semiconductor package is embedded in an interposer substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating a fan-out semiconductor package according to a first exemplary embodiment in the present disclosure;

FIG. 10 is a view for describing connection between a passive element and passive element connection vias of the fan-out semiconductor package according to a first exemplary embodiment in the present disclosure;

FIG. 11 is a view illustrating a modified example of passive element connection vias;

FIG. 12 is a schematic cross-sectional view illustrating a fan-out semiconductor package according to a second exemplary embodiment in the present disclosure; and

FIG. 13 is a schematic cross-sectional view illustrating a fan-out semiconductor package according to a third exemplary embodiment in the present disclosure.

### DETAILED DESCRIPTION

Hereinafter, exemplary embodiments of the present disclosure will now be described in detail with reference to the accompanying drawings. In the accompanying drawings, shapes, sizes, and the like, of components may be exaggerated or stylized for clarity.

The present disclosure may, however, be exemplified in many different forms and should not be construed as being limited to the specific embodiments set forth herein. Rather these embodiments are provided so that this disclosure will be thorough and complete, and will fully convey the scope of the disclosure to those skilled in the art.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with another. For example, one element described in a particular exemplary embodiment, even if it is not described in another exemplary embodiment, may be understood as a description related to another exemplary embodiment, unless an opposite or contradictory description is provided therein.

The meaning of a “connection” of a component to another component in the description includes an indirect connection through a third component as well as a direct connection between two components. In addition, “electrically connected” means the concept including a physical connection and a physical disconnection. It can be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

Herein, an upper portion, a lower portion, an upper side, a lower side, an upper surface, a lower surface, and the like, are decided in the accompanying drawings. For example, a first connection member is disposed on a level above a redistribution layer. However, the claims are not limited thereto. In addition, a vertical direction refers to the abovementioned upward and downward directions, and a horizontal direction refers to a direction perpendicular to the abovementioned upward and downward directions. In this case, a vertical cross section refers to a case taken along a plane in the vertical direction, and an example thereof may be a cross-sectional view illustrated in the drawings. In addition, a horizontal cross section refers to a case taken along a plane in the horizontal direction, and an example thereof may be a plan view illustrated in the drawings.

Terms used herein are used only in order to describe an exemplary embodiment rather than limiting the present disclosure. In this case, singular forms include plural forms unless interpreted otherwise in context.

Electronic Device

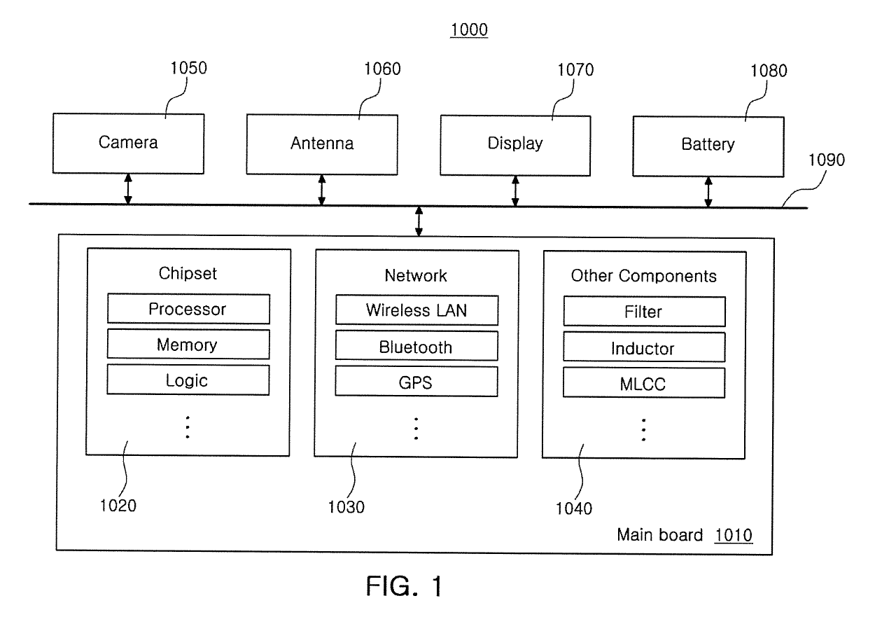

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

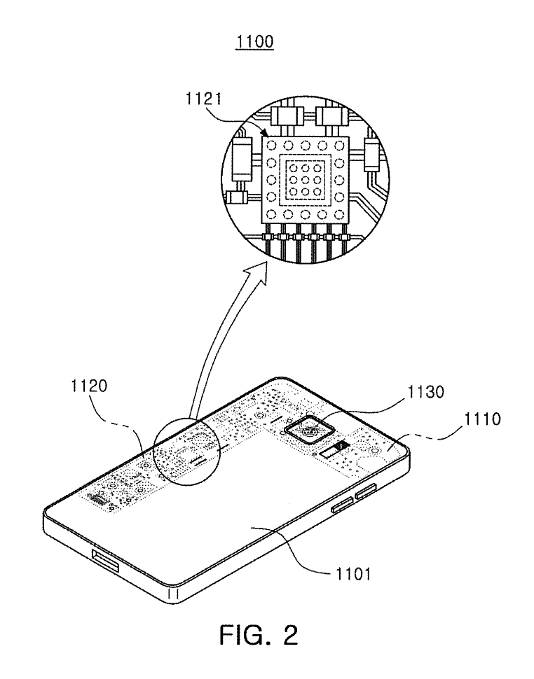

FIG. 2 is a schematic perspective view illustrating an example of an electronic device.

Referring to FIG. 2, a semiconductor package may be used for various purposes in the various electronic devices 1000 as described above. For example, a mainboard 1110 may be accommodated in a body 1101 of a smartphone 1100, and various electronic components 1120 may be physically or electrically connected to the mainboard 1110. In addition, other components that may or may not be physically or electrically connected to the mainboard 1010, such as a camera module 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

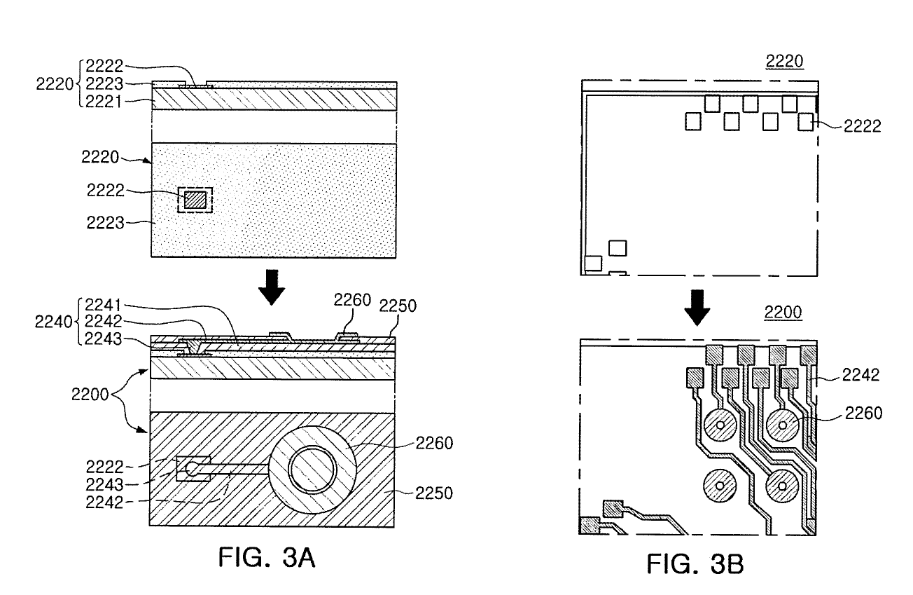

FIGS. 3A and 3B are schematic cross-sectional views illustrating states of a fan-in semiconductor package before and after being packaged.

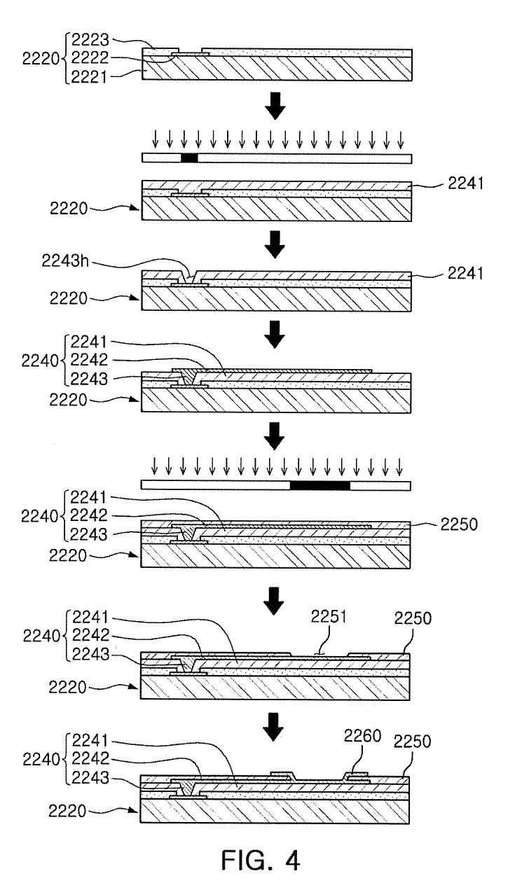

FIG. 4 is schematic cross-sectional views illustrating a packaging process of a fan-in semiconductor package.

Referring to FIGS. 3A through 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package foam. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in electronic component package on the mainboard of the electronic device.

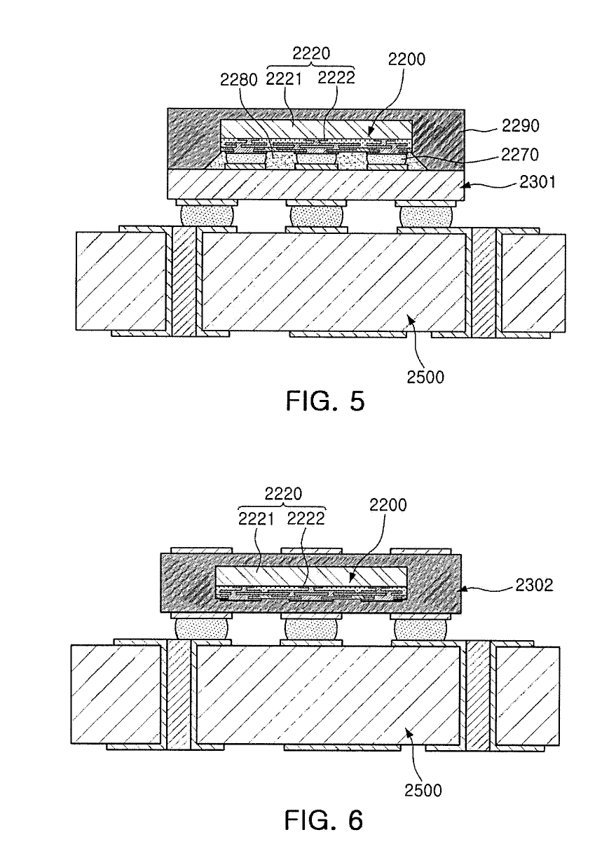

FIG. 5 is a schematic cross-sectional view illustrating a case in which a fan-in semiconductor package is mounted on an interposer substrate and is ultimately mounted on a mainboard of an electronic device.

FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may be ultimately mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with an encapsulant 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-out Semiconductor Package

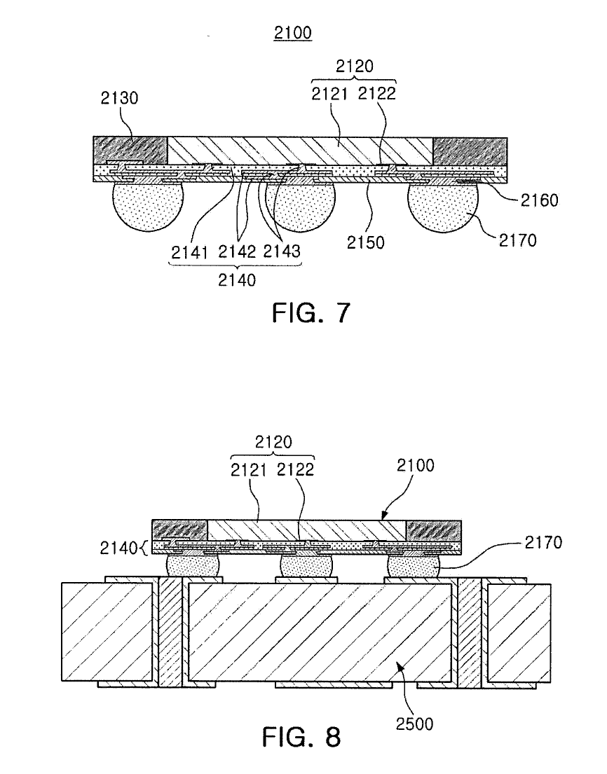

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate interposer substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out electronic component package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

Fan-out semiconductor packages according to exemplary embodiments in the present disclosure will hereinafter be described with reference to the drawings.

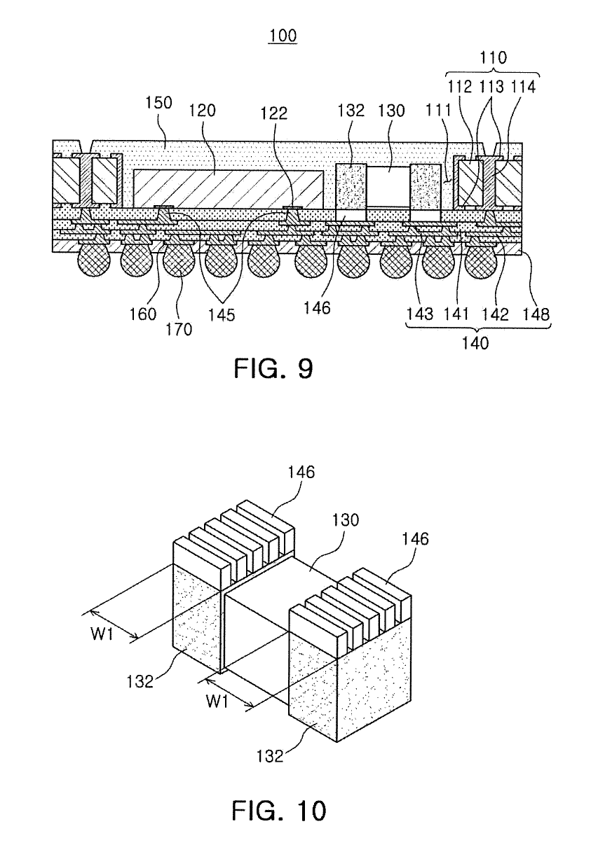

FIG. 9 is a schematic cross-sectional view illustrating a fan-out semiconductor package according to a first exemplary embodiment in the present disclosure, and FIG. 10 is a view for describing connection between a passive element and passive element connection vias of the fan-out semiconductor package according to a first exemplary embodiment in the present disclosure.

Referring to FIGS. 9 and 10, a fan-out semiconductor package 100 according to a first exemplary embodiment in the present disclosure may include a core member 110, a semiconductor chip 120, a passive element 130, a redistribution member 140, and an encapsulant 150 as an example.

At least one through-hole 111 may be formed in the core member 110. As an example, the core member 110 may be provided to support the fan-out semiconductor package 100, and may maintain rigidity and secure uniformity of a thickness.

In the present exemplary embodiment, the semiconductor chip 120 and the passive element 130 may be disposed in the through-hole 111 of the core member 110. In addition, side surfaces of the semiconductor chip 120 and the passive element 130 may be surrounded by the core member 110. However, such a form is only an example and may be variously modified to have other forms, and the core member 110 may perform another function depending on such a form. The core member 110 may be omitted, if necessary, but it may be advantageous in securing board level reliability that the fan-out semiconductor package 100 includes the core member 110.

Meanwhile, an insulating layer 112 of the core member 110 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, Ajinomoto Build-up Film (ABF), FR-4, Bismaleimide Triazine (BT), or the like, but is not limited thereto. A metal having excellent rigidity and thermal conductivity may be disposed in the insulating layer 112. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the insulating layer 112. In addition, the insulating layer 112 may serve as a support member.

Meanwhile, the core member 110 may include wiring layers 113 and connection vias 114. In this case, the fan-out semiconductor package 100 may be utilized as a package-on-package (POP) type package. In detail, the core member 110 may include the wiring layers 113 and the connection vias 114 connected to the wiring layers 113. A case in which the wiring layers 113 are formed on only an upper surface and a lower surface of the insulating layer 112 is illustrated in FIG. 10, but the wiring layer 113 may also be formed in the insulating layer 112.

The semiconductor chip 120 may be disposed in the through-hole 111. As an example, the semiconductor chip 120 may be an integrated circuit (IC) provided in an amount of several hundred to several million elements integrated in a single chip, an active element, or the like. The semiconductor chip 120 may also be a semiconductor chip in which an integrated circuit is packaged in a flip-chip form, if necessary. The IC may be, for example, an application processor chip such as a central processor (for example, a CPU), a graphic processor (for example, a GPU), a digital signal processor, a cryptographic processor, a micro-processor, a micro-controller, or the like, but is not limited thereto.

Meanwhile, connection pads 122 for electrical connection may be formed on the semiconductor chip 120. The connection pads 122 may be used to electrically externally connect the semiconductor chip 120. In addition, the connection pads 122 may be connected to a redistribution member 140 to be described below.

The passive element 130 may be disposed in the through-hole 111 so as not to interfere with the semiconductor chip 120. As an example, the passive element 130 may be disposed side by side with the semiconductor chip 120 in a horizontal direction within the through-hole 111.

Meanwhile, external electrodes 132 for electrical connection may be provided on opposite end portions of the passive element 130, respectively.

The passive element 130 may be any one of a resistor, a capacitor, an inductor, a trance, and a relay as an example, and may serve to consume energy, accumulate energy therein, or pass energy therethrough.

In addition, as an example, when the passive element 130 includes a decoupling capacitor provided in order to stably supply power to the semiconductor chip 120, and the like, the passive element 130 may be connected to the semiconductor chip 120 to serve as a decoupling capacitor.

In addition, the external electrodes 132 of the passive element 130 may be connected to a redistribution member 140 to be described below.

The redistribution member 140 may be electrically connected to the semiconductor chip 120 and the passive element 130, and may be disposed on one surface of the core member 110. For example, the redistribution member 140 may redistribute the connection pads 122 of the semiconductor chip 120, and may electrically connect the wiring layer 113 of the core member 110 to the connection pads 122 of the semiconductor chip 120. Several tens to several millions of connection pads of the semiconductor chip having various functions may be redistributed by the redistribution member 140, and may be physically or electrically externally connected through electrical connection structures 170 depending on functions.

The redistribution member 140 may include one or more insulating layers 141, one or more redistribution layers 142 disposed in the insulating layer 141, and vias 143 penetrating through the insulating layers 141 and connecting the redistribution layers 142 to each other. In addition, the numbers of insulating layers 141, redistribution layers 142, and layers of the vias 143 may be variously modified.

In addition, a material of each of the insulating layers 141 may be an insulating material. In this case, a photosensitive insulating material such as a PID resin may also be used as the insulating material. That is, each of the insulating layers 141 may be a photosensitive insulating layer. When the insulating layer 141 has photosensitive properties, the insulating layer 141 may be formed to have a smaller thickness, and a fine pitch of the via 143 may be achieved more easily. Each of the insulating layers 141 may be a photosensitive insulating layer including an insulating resin and an inorganic filler. When the insulating layers 141 are multiple layers, materials of the insulating layers 141 may be the same as each other, and may also be different from each other, if necessary. When the insulating layers 141 are the multiple layers, the insulating layers 141 may be integrated with each other depending on a process, such that a boundary therebetween may also not be apparent.

The redistribution layers 142 may substantially serve to redistribute the connection pads 122. A material of each of the redistribution layers 142 may be a conductive material such as copper (Cu), aluminum (Al), silver (Ag), tin (Sn), gold (Au), nickel (Ni), lead (Pb), titanium (Ti), or alloys thereof. The redistribution layers 142 may perform various functions depending on designs of corresponding layers. For example, the redistribution layers 142 may include ground patterns, power patterns, signal patterns, and the like. Here, the signal patterns may include various signals except for the ground patterns, the power patterns, and the like, such as data signals, and the like. In addition, the redistribution layers 142 may include various pad patterns.

Meanwhile, the redistribution member 140 may include chip connection vias 145 for connecting the redistribution layer 142 and the connection pads 122 of the semiconductor chip 120 to each other. A longitudinal cross section of each of the chip connection vias 145 may have any one of a tapered shape and a cylindrical shape. In addition, each of the chip connection vias 145 may be formed of a conductive material such as copper (Cu), aluminum (Al), silver (Ag), tin (Sn), gold (Au), nickel (Ni), lead (Pd), titanium (Ti), or alloys thereof.

In addition, the redistribution member 140 may include passive element connection vias 146 for connecting the redistribution layer 142 and the external electrodes 132 of the passive element 130 to each other. Meanwhile, a transverse cross section of each of the passive element connection vias 146 may have a rectangular shape. As an example, each of the passive element connection vias 146 may have the same width as a width W1 as that of each of the external electrodes 132 provided on the passive element 130.

In addition, a plurality of passive element connection vias 146 may be disposed side by side in a length direction on each of the external electrodes 132 of the passive element 130. Further, the plurality of passive element connection vias 146 may be disposed to be spaced apart from each other in the length direction of the passive element 130.

As described above, contact areas between the passive element connection vias 146 and the external electrodes 132 of the passive element 130 may be increased through the passive element connection vias 146. Therefore, reliability of a product may be improved.

Further, even in a case in which the passive element 130 is misaligned, the passive element connection vias 146 and the external electrodes 132 of the passive element 130 may be stably connected to each other.

Meanwhile, the insulating layer 141 may have openings exposing the chip connection vias 145 and the passive element connection vias 146.

A passivation layer 148 may protect the redistribution member 140 from external physical or chemical damage. The passivation layer 148 may have openings exposing at least portions of the redistribution layer 142. Meanwhile, a material of the passivation layer 148 is not particularly limited, but may be, for example, an insulating material. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used.

The encapsulant 150 may encapsulate the core member 110, the semiconductor chip 120, and the passive element 130. In addition, a material of the encapsulant 150 is not particularly limited. For example, an insulating material may be used as the material of the encapsulant 150. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a PID resin may also be used as the insulating material.

The underbump metal layers 160 may improve connection reliability of the electrical connection structures 170 to improve board level reliability of the fan-out semiconductor package 100. The underbump metal layers 160 may be connected to the redistribution layer 142 through the vias 143. The underbump metal layers 160 may be formed by any known metallization method using any known conductive material such as a metal, but are not limited thereto.

The electrical connection structures 170 may physically or electrically externally connect the fan-out semiconductor package 100. For example, the fan-out semiconductor package 100 may be mounted on the mainboard of the electronic device through the electrical connection structures 170. Each of the electrical connection structures 170 may be formed of a conductive material, for example, a solder, or the like. However, this is only an example, and a material of each of the electrical connection structures 170 is not particularly limited thereto. Each of the electrical connection structures 170 may be a land, a ball, a pin, or the like. The electrical connection structures 170 may be formed as a multilayer or single layer structure. When the electrical connection structures 170 are formed as a multilayer structure, the electrical connection structures 170 may include a copper (Cu) pillar and a solder. When the electrical connection structures 170 are formed as a single layer structure, the electrical connection structures 170 may include a tin-silver solder or copper (Cu). However, this is only an example, and the electrical connection structures 170 are not limited thereto.

The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several thousands according to the number of connection pads 122, or may be provided in an amount of several tens to several thousands or more or several tens to several thousands or less. When the electrical connection structures 170 are solder balls, the electrical connection structures 170 may cover side surfaces of the underbump metal layers 160 extending onto one surface of the passivation layer 148, and connection reliability may be more excellent.

At least one of the electrical connection structures 170 may be disposed in a fan-out region. The fan-out region refers to a region except for a region in which the semiconductor chip 120 is disposed. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be manufactured to have a small thickness, and may have price competitiveness.

As described above, the contact areas between the passive element connection vias 146 and the external electrodes 132 of the passive element 130 may be increased through the passive element connection vias 146. Therefore, the reliability of the product may be improved.

Further, even in the case in which the passive element 130 is misaligned, the passive element connection vias 146 and the external electrodes 132 of the passive element 130 may be stably connected to each other.

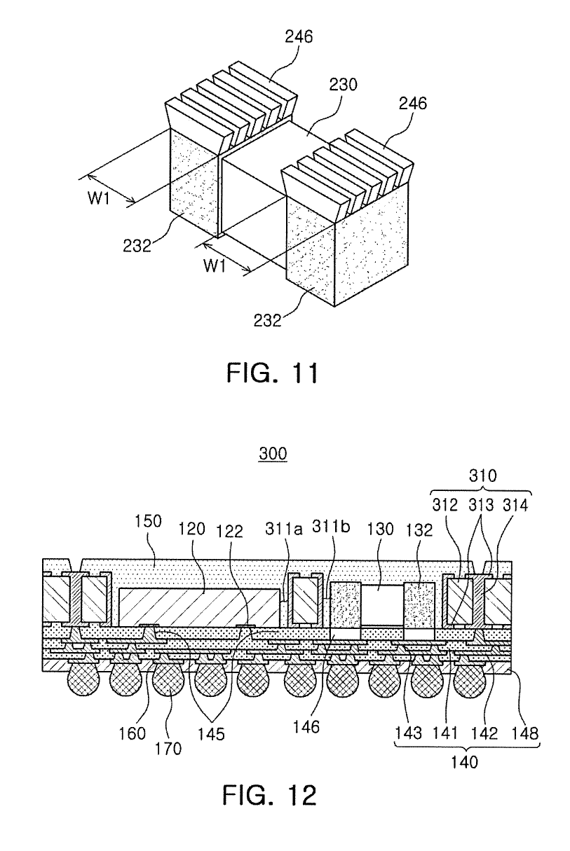

FIG. 11 is a view illustrating a modified example of passive element connection vias.

Referring to FIG. 11, a lower end portion (i.e., the portion relatively closer to the respective external electrode) of each of passive element connection vias 246 may have the same width as a width W1 as that of each of external electrodes 232 provided on a passive element 230, and an upper end portion (i.e., the portion relatively closer to the redistribution layer) of each of the passive element connection vias 246 may have a width greater than that the width W1 as that of each of the external electrodes 232 provided on the passive element 230.

FIG. 12 is a schematic cross-sectional view illustrating a fan-out semiconductor package according to a second exemplary embodiment in the present disclosure.

Referring to FIG. 12, a fan-out semiconductor package 300 according to a second exemplary embodiment in the present disclosure may include a core member 310, a semiconductor chip 120, a passive element 130, a redistribution member 140, and an encapsulant 150 as an example.

A first through-hole 311a in which the semiconductor chip 120 is disposed and a second through-hole 311b, disposed to be spaced apart from the first through-hole 311a and in which the passive element 130 is disposed may be formed in the core member 310.

As an example, the core member 310 may be provided to support the fan-out semiconductor package 300, and may maintain rigidity and secure uniformity of a thickness.

In the present exemplary embodiment, the semiconductor chip 120 and the passive element 130 may be disposed in the first and second through-hole 311a and 311b of the core member 310, respectively. In addition, side surfaces of the semiconductor chip 120 and the passive element 130 may be surrounded by the core member 310. However, such a form is only an example and may be variously modified to have other forms, and the core member 310 may perform another function depending on such a form. The core member 310 may be omitted, if necessary, but it may be advantageous in securing board level reliability that the fan-out semiconductor package 300 includes the core member 310.

Meanwhile, an insulating layer 312 of the core member 310 may be formed of an insulating material. The insulating material may be a thermosetting resin such as an epoxy resin, a thermoplastic resin such as a polyimide resin, a resin having a reinforcement material such as a glass fiber or an inorganic filler impregnated in the thermosetting resin and the thermoplastic resin, for example, prepreg, ABF, FR-4, BT, or the like, but is not limited thereto. A metal having excellent rigidity and thermal conductivity may be disposed in the insulating layer 312. In this case, the metal may be an Fe—Ni-based alloy, and a Cu plating layer may be formed on a surface of the Fe—Ni-based alloy. In addition to the materials as described above, glass, ceramic, plastic, or the like, may also be disposed in the insulating layer 312. In addition, the insulating layer 312 may serve as a support member.

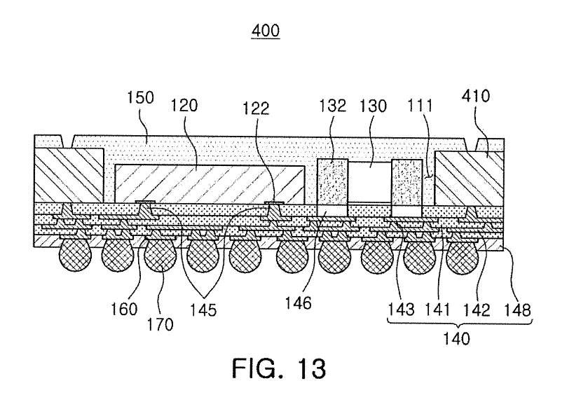

Meanwhile, the core member 310 may include wiring layers 313 and connection vias 314. In this case, the fan-out semiconductor package 300 may be utilized as a package-on-package (POP) type package. In detail, the core member 310 may include the wiring layers 313 and the connection vias 314 connected to the wiring layers 313. A case in which the wiring layers 313 are formed on only an upper surface and a lower surface of the insulating layer 312 is illustrated in FIG. 13, but the wiring layer 313 may also be formed in the insulating layer 312. Moreover, the wiring layer 313 may only be formed on a lower surface of the insulating layer 312 in some cases.

Meanwhile, the redistribution member 140 may be electrically connected to the semiconductor chip 120 and the passive element 130, and may be disposed on one surface of the core member 310. For example, the redistribution member 140 may redistribute the connection pads 122 of the semiconductor chip 120, and may electrically connect the wiring layer 313 of the core member 310 to the connection pads 122 of the semiconductor chip 120. Several tens to several millions of connection pads of the semiconductor chip having various functions may be redistributed by the redistribution member 140, and may be physically or electrically externally connected through electrical connection structures 170 depending on functions.

The redistribution member 140 may include one or more insulating layers 141, one or more redistribution layers 142 disposed in the insulating layer 141, and vias 143 penetrating through the insulating layers 141 and connecting the redistribution layers 142 to each other. In addition, the numbers of insulating layers 141, redistribution layers 142, and layers of the vias 143 may be variously modified.

In addition, a material of each of the insulating layers 141 may be an insulating material. In this case, a photosensitive insulating material such as a PID resin may also be used as the insulating material. That is, each of the insulating layers 141 may be a photosensitive insulating layer. When the insulating layer 141 has photosensitive properties, the insulating layer 141 may be formed to have a smaller thickness, and a fine pitch of the via 143 may be achieved more easily. Each of the insulating layers 141 may be a photosensitive insulating layer including an insulating resin and an inorganic filler. When the insulating layers 141 are multiple layers, materials of the insulating layers 141 may be the same as each other, and may also be different from each other, if necessary. When the insulating layers 141 are the multiple layers, the insulating layers 141 may be integrated with each other depending on a process, such that a boundary therebetween may also not be apparent.

The redistribution layers 142 may substantially serve to redistribute the connection pads 122. A material of each of the redistribution layers 142 may be a conductive material such as copper (Cu), aluminum (Al), silver (Ag), tin (Sn), gold (Au), nickel (Ni), lead (Pb), titanium (Ti), or alloys thereof. The redistribution layers 142 may perform various functions depending on designs of corresponding layers. For example, the redistribution layers 142 may include ground patterns, power patterns, signal patterns, and the like. Here, the signal patterns may include various signals except for the ground patterns, the power patterns, and the like, such as data signals, and the like. In addition, the redistribution layers 142 may include various pad patterns.

Meanwhile, the redistribution member 140 may include chip connection vias 145 for connecting the redistribution layer 142 and the connection pads 122 of the semiconductor chip 120 to each other. A longitudinal cross section of each of the chip connection vias 145 may have any one of a tapered shape and a cylindrical shape. In addition, each of the chip connection vias 145 may be formed of a conductive material such as copper (Cu), aluminum (Al), silver (Ag), tin (Sn), gold (Au), nickel (Ni), lead (Pd), titanium (Ti), or alloys thereof.

In addition, the redistribution member 140 may include passive element connection vias 146 for connecting the redistribution layer 142 and the external electrodes 132 of the passive element 130 to each other. Meanwhile, a transverse cross section of each of the passive element connection vias 146 may have a rectangular shape. As an example, each of the passive element connection vias 146 may have the same width as a width W1 of each of the external electrodes 132 provided on the passive element 130.

In addition, a plurality of passive element connection vias 146 may be disposed side by side in a length direction on each of the external electrodes 132 of the passive element 130. Further, the plurality of passive element connection vias 146 may be disposed to be spaced apart from each other in the length direction of the passive element 130.

As described above, contact areas between the passive element connection vias 146 and the external electrodes 132 of the passive element 130 may be increased through the passive element connection vias 146. Therefore, reliability of a product may be improved.

Further, even in the case in which the passive element 130 is misaligned, the passive element connection vias 146 and the external electrodes 132 of the passive element 130 may be stably connected to each other.

Meanwhile, the insulating layer 141 may have openings exposing the chip connection vias 145 and the passive element connection vias 146.

A passivation layer 148 may protect the redistribution member 140 from external physical or chemical damage. The passivation layer 148 may have openings exposing at least portions of the redistribution layer 142. Meanwhile, a material of the passivation layer 148 is not particularly limited, but may be, for example, an insulating material. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. Alternatively, a solder resist may also be used.

As described above, the contact areas between the passive element connection vias 146 and the external electrodes 132 of the passive element 130 may be increased through the passive element connection vias 146. Therefore, the reliability of the product may be improved.

Further, even in the case in which the passive element 130 is misaligned, the passive element connection vias 146 and the external electrodes 132 of the passive element 130 may be stably connected to each other.

FIG. 13 is a schematic cross-sectional view illustrating a fan-out semiconductor package according to a third exemplary embodiment in the present disclosure.

Referring to FIG. 13, a fan-out semiconductor package 400 according to a third exemplary embodiment in the present disclosure may include a core member 410, a semiconductor chip 120, a passive element 130, a redistribution member 140, and an encapsulant 150 as an example.

Meanwhile, the semiconductor chip 120, the passive element 130, the redistribution member 140, and the encapsulant 150 are the same components as those described above, and a detailed description therefor is thus omitted.

Referring to FIG. 13, the core member 410 may only include an insulating layer. An insulating material of the insulating layer may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, ABF, FR-4, BT, or the like. The core member 410 may serve as a support member.

Meanwhile, the core member 410 may not include the wiring layer 113 and the connection vias 114 unlike the core member 110 included in the fan-out semiconductor package 100 according to the first exemplary embodiment in the present disclosure described above.

As set forth above, according to an exemplary embodiment, electrical connection to a passive element may be easily performed even though a manufacturing error occurs, and contact areas between the passive element and vias may be increased.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a semiconductor chip;
a passive element disposed side by side with the semiconductor chip in a horizontal direction;
a redistribution member electrically connected to the semiconductor chip and the passive element and disposed beneath the semiconductor chip and the passive element, the redistribution member comprising passive element connection vias having a rectangular transverse cross section for electrically connecting the passive element; and
an encapsulant encapsulating the semiconductor chip and the passive element.

2. The fan-out semiconductor package of claim 1, wherein the passive element connection via has the same width as that of an external electrode provided on the passive element.

3. The fan-out semiconductor package of claim 1, wherein a portion of the passive element connection via relatively closer to an external electrode of the passive element has the same width as that of the external electrode provided on the passive element, and an portion of the passive element connection via relatively closer to the redistribution member has a width greater than that of the external electrode provided on the passive element.

4. The fan-out semiconductor package of claim 1, wherein a plurality of passive element connection vias are disposed side by side in a length direction on each external electrode disposed on opposite end portions of the passive element.

5. The fan-out semiconductor package of claim 4, wherein the plurality of passive element connection vias are disposed to be spaced apart from each other in a length direction.

6. The fan-out semiconductor package of claim 1, wherein the redistribution member includes chip connection vias connected to the semiconductor chip, and the chip connection vias are disposed to be spaced apart from the passive element connection vias.

7. The fan-out semiconductor package of claim 6, wherein a longitudinal cross section of the chip connection via has any one of a tapered shape and a cylindrical shape.

8. The fan-out semiconductor package of claim 1, further comprising a core member including a through-hole in which the semiconductor chip and the passive element are disposed.

9. The fan-out semiconductor package of claim 8, wherein the core member includes an insulating layer in which the through-hole is formed, a redistribution layer formed on at least one of an upper surface and a lower surface of the insulating layer, and connection vias connected to the redistribution layer.

10. The fan-out semiconductor package of claim 1, further comprising a core member including a first through-hole in which the semiconductor chip is disposed and a second through-hole, disposed to be spaced apart from the first through-hole and in which the passive element is disposed.

11. The fan-out semiconductor package of claim 10, wherein the redistribution member includes chip connection vias connected to the semiconductor chip and the passive element connection vias connected to the passive element.

12. The fan-out semiconductor package of claim 11, wherein a longitudinal cross section of the chip connection via has any one of a tapered shape and a cylindrical shape, and the passive element connection via has the same width as that of an external electrode provided on the passive element.

13. The fan-out semiconductor package of claim 8, wherein the core member only includes an insulating layer.

14. The fan-out semiconductor package of claim 1, wherein the redistribution member includes one or more insulating layers, one or more redistribution layers disposed in the insulating layer, and vias connecting the redistribution layers to each other.

15. A fan-out semiconductor package, comprising:
a redistribution member comprising passive element connection vias and chip connection vias exposed to a first surface of the redistribution member, the passive element connection vias having a rectangular cross-section when viewed in a plane perpendicular to the first surface in a length direction, the chip connection vias and the passive element connection vias penetrating a thickness of the redistribution member perpendicular to the first surface;
a semiconductor chip having connection pads disposed on the redistribution member such that the connection pads face the first surface and are electrically connected to the chip connection vias;
a passive element disposed adjacent the semiconductor chip along the first surface, having external electrodes spaced apart from each other in the length direction, electrically connected to corresponding passive element connection vias; and
an encapsulant encapsulating the semiconductor chip and the passive element.

16. The fan-out semiconductor package of claim 15, wherein the redistribution member further comprises an insulating layer having the first surface and a redistribution wiring layer, wherein the chip connection vias and the passive element connection vias respectively electrically connect the semiconductor chip and the passive element to the redistribution wiring layer.

17. The fan-out semiconductor package of claim 15, wherein each external electrode of the passive element contacts a plurality of passive element connection vias spaced apart from each other in a width direction perpendicular to the length direction.

18. The fan-out semiconductor package of claim 15, wherein a portion of each of the passive element connection vias relatively closer to the corresponding external electrode along the thickness of the redistribution member has a smaller area than a portion relatively farther from the corresponding external electrode along the thickness of the redistribution member.
